(19) United States
(12) Patent Application Publication
(10) Pub. No.: US 2009/0032681 A1
(43) Pub. Date: Feb. 5, 2009

(54) Detector and detecting method

(75) Inventors: Sheng-Feng Lu, Hsinchu (TW); Choy-Shin Cheong, Hsinchu (TW); Shih-Ming Chen, Kaohsiung (TW); Li-Ming Chin, Kaohsiung (TW); Shih-Hua Hsu, Nantou (TW)

Correspondence Address: Joe McKinney Muncy, PO Box 1364, Fairfax, VA, 22038-1364, US

(73) Assignee: VisEra Technologies Company Limited

(21) Appl. No.: 11/976,060

(22) Filed: Oct. 19, 2007

(30) Foreign Application Priority Data
Jul. 30, 2007 (TW) 096127722

(51) Int. Cl. H01L 27/00

(52) U.S. Cl. 250/208.1

(57) ABSTRACT

A detector for detecting an image sensor is provided. The image sensor is electrically connected to a wafer via a contacting pad. The detector includes a parallel light source, a pin and a diffuser. The parallel light source radiates a parallel light. The pin is electrically connected to the contacting pad. The diffuser is disposed between the parallel light source and the pin. The parallel light from the parallel light source passes through the diffuser and then reaches the image sensor on the wafer.

### BACKGROUND OF THE INVENTION

1. Field of the Invention

The invention relates to a detector and a detecting method, and more particularly to a detector and a detecting method to detect an image sensor.

2. Description of the Related Art

FIG. 1 is a schematic view of a conventional detector 10. Referring to FIG. 1, the conventional detector 10 for detecting an image sensor 20 comprises a parallel light source 11, a printed circuit board 12, a pin 13 and a gap 14. The image sensor 20 is disposed on and electrically connected to the wafer 21 via a contacting pad 22. The printed circuit board 12 is electrically connected to the pin 13. The gap 14 which is an optical path is disposed on the printed circuit board 12. The parallel light source 11 and the image sensor 20 are correspondingly disposed on the upper and lower ends of the printed circuit board 12. When the detector 10 detects the image sensor 20, the parallel light source 11 radiates a parallel light. The parallel light enters the gap 14 along an arrow A as shown in FIG. 1. The pin 13 of the detector 10 is electrically connected to the contacting pad 22. After receiving the light, the image sensor 20 generates an electric signal. Then, the electric signal is transmitted to a printed circuit board 12 of the detector 10 via the pin 13 to decide if the image sensor 20 is operational or not.

The conventional detector 10 provides parallel light to enter the image sensor 20. However, when the image sensor 20 is used in daily circumstances under a natural environment, the light in the environment is not always parallel light. Thus, there is a discrepancy between the detecting result using the parallel light and natural environment light. As such, the conventional detector 10 does not accurately detect the light in daily circumstances for the image sensor 20. Therefore, adjustments must be made to the image sensor 20.

### BRIEF SUMMARY OF INVENTION

A detailed description is given in the following embodiments with reference to the accompanying drawings. The invention provides a detector for detecting an image sensor. The image sensor is electrically connected to a wafer. A contacting pad is disposed between the image sensor and the wafer. The detector comprises a parallel light source, a pin, and a diffuser. The parallel light source radiates a parallel light. The pin is electrically connected to the contacting pad. The diffuser is disposed between the parallel light source and the pin. The parallel light of the parallel light source passes through the diffuser and reaches the image sensor and the wafer.

The invention provides a detecting method for detecting an image sensor. The image sensor is electrically connected to a wafer. A contacting pad is disposed between the image sensor and the wafer. The steps of the detecting method comprises: providing a detector, wherein the detector comprises a parallel light, a pin, a diffuser and a lens; allowing the parallel light to pass through the diffuser; allowing the parallel light passing through the diffuser to become a diffusing light; and forming an image on the image sensor.

Note that the steps further comprise, allowing the diffusing light to pass through the lens. Note also that the steps further comprise, electrically connecting the pin and the contacting pad.

### BRIEF DESCRIPTION OF DRAWINGS

The invention can be more fully understood by reading the subsequent detailed description and examples with references made to the accompanying drawings, wherein:

FIG. 1 is a schematic view of a conventional detector;

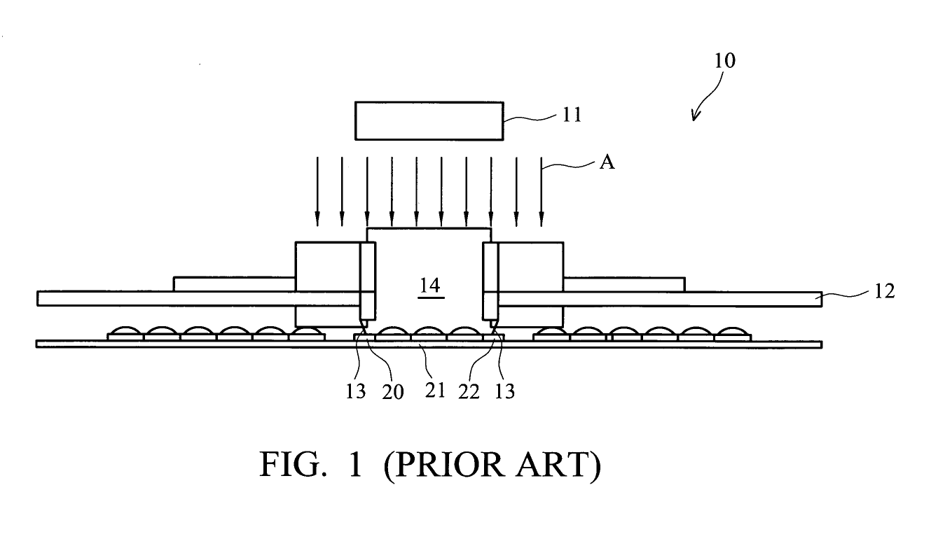

FIG. 2 is a schematic view of a detector of the invention;

FIG. 3 is a schematic view of another embodiment of a detector;

FIG. 4 is a schematic view of a holder and a lens; and

FIG. 5 is a flow chart of a detecting method using the detector.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

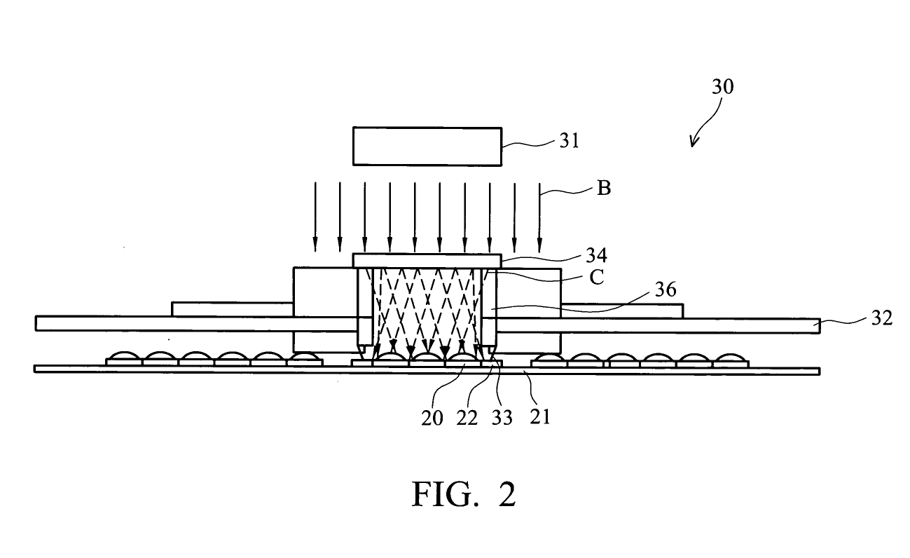

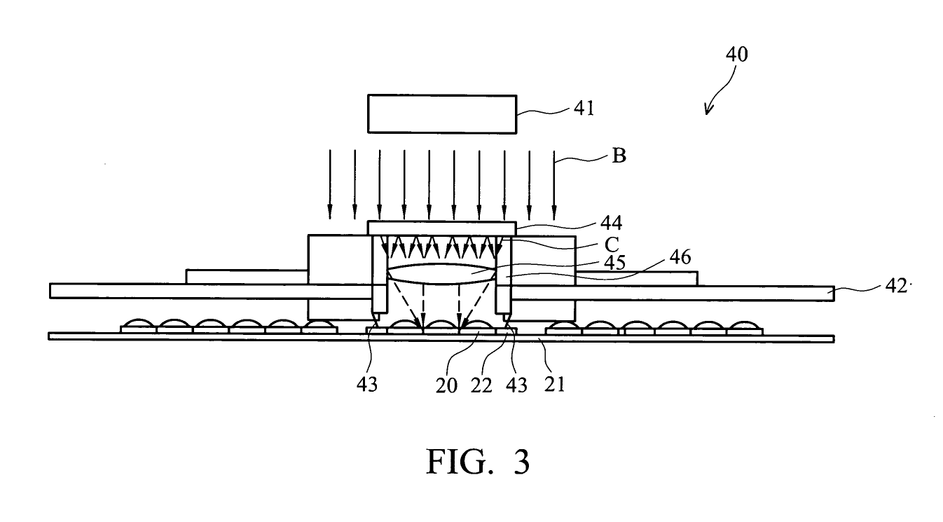

FIG. 2 is a schematic view of a detector 30 of the invention. Referring to FIG. 2, a detector 30 is provided for detecting an image sensor 20. The image sensor 20 is electrically connected to a wafer 21. A contacting pad 22 is disposed between the image sensor 20 and the wafer 21. The detector 30 comprises a parallel light source 31, a printed circuit board 32, a pin 33 and a diffuser 34. The parallel light source 31 radiates a parallel light. The pin 33 is electrically connected to the printed circuit board 32. The diffuser 34 is disposed between the parallel light source 31 and the pin 33. The parallel light passes through the diffuser 34 along an arrow B to become a diffusing light (shown in FIG. 3). Then, the diffusing light reaches the image sensor 20. The pin 33 of the detector 30 is connected to the contacting pad 22. After the diffusing light reaching, an electric signal materializes via the image sensor 20 and the wafer 21. The electric signal is transmitted to the printed circuit board 32 of the detector 30 to decide if the image sensor 20 is operational or not. In this embodiment, the detector 30 comprising the diffuser 34 imitates the light (diffusing light) in daily circumstances under a natural environment for the image sensor 20 to increase accuracy of the detecting result. Note that the image sensor 20 may be a charge coupled device (CCD) or contact image sensors (CIS).

FIG. 3 is a schematic view of another embodiment of a detector 40. Referring to FIG. 3, a detector 40 is provided for detecting an image sensor 20. The image sensor 20 is electrically connected to a wafer 21. A contacting pad 22 is disposed between the image sensor 20 and the wafer 21. The detector 40 comprises a parallel light source 41, a printed circuit board 42, a pin 43, a diffuser 44, a lens 45 and a holder 46. The parallel light source 41 radiates a parallel light. The pin 43 is electrically connected to the printed circuit board 42. The diffuser 44 is disposed between the parallel light source 41 and the pin 43. The holder 46 holds the lens 45. The holder 46 is disposed between the diffuser 44 and the pin 43. The parallel light passes through the diffuser 44 along an arrow B to become a diffusing light (arrow C). Then, the diffusing light passes through the lens 45 for focusing and reaches the image sensor 20. The pin 43 of the detector 40 is connected to the contacting pad 22. After the diffusing light reaches the image sensor 20, an electric signal materializes via the image sensor 20 and the wafer 21. The electric signal is transmitted to the printed circuit board 42 of the detector 40 via the pin 43 to judge if the image sensor 20 works or not. In this embodiment, the detector 40 comprising the diffuser 44 imitates the light (diffusing light) in daily circumstances under a natural environment for the image sensor 20 to increase accuracy of the detecting result. Normally, the image sensor 20 and the lens 45 are used together. Thus, the detecting result using the lens 45 disposed between the diffuser 44 and the pin 43 is similar to the use result of the image sensor 20 in the daily circumstances under a natural environment. As a result, the accuracy of the detecting result increases. Note that the image sensor 20 may be a charge coupled device (CCD) or contact image sensors (CIS).

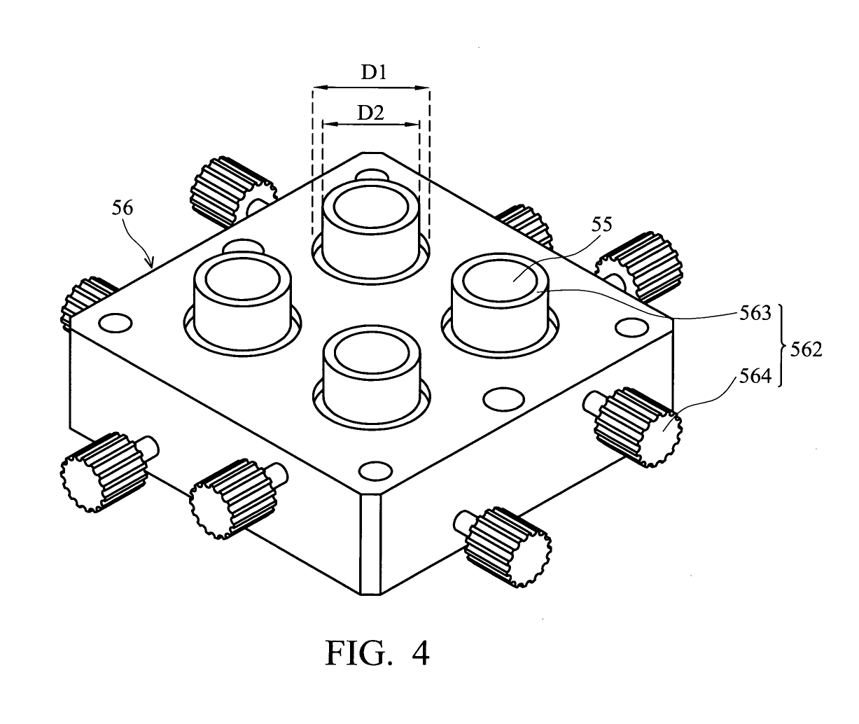

FIG. 4 is a schematic view of a holder 56 and a lens 55. The holder 56 comprises an adjusting mechanism 562. The adjusting mechanism 562 comprises an accommodating portion 563 and a trimmer screw 564. The accommodating portion 563 contains the lens 55. The trimmer screw 564 is connected to the lens 55. The trimmer screw 564 is rotated to move the lens 55. Note that the bore diameter D1 of the accommodating portion 563 is greater than the diameter D2 of the lens 55.

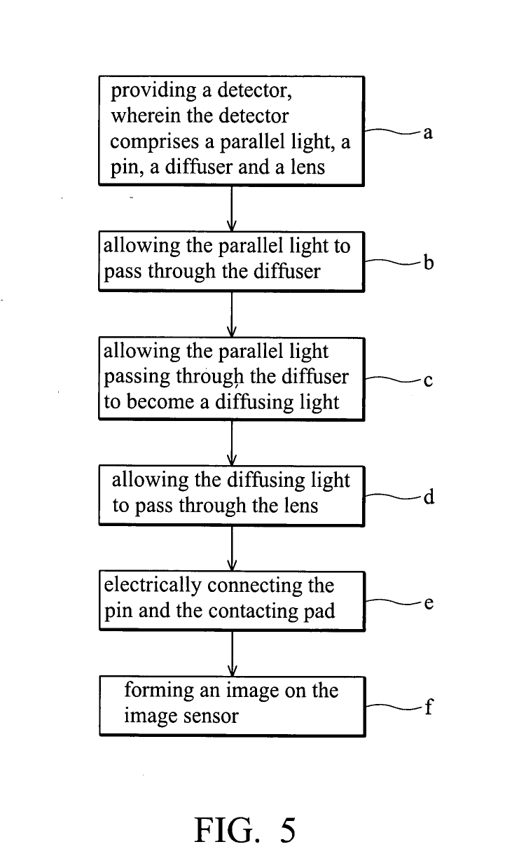

FIG. 5 is a flow chart of a detecting method using the detector 40. The detecting method is provided to detect an image sensor 20. Referring to FIGS. 3 and 5, the image sensor 20 is electrically connected to a wafer 21. A contacting pad 22 is disposed between the image sensor 20 and the wafer 21. The steps of the detecting method comprises: a. providing a detector 40, wherein the detector 40 comprises a parallel light, a pin 43, a diffuser 44 and a lens 45; b. allowing the parallel light to pass through the diffuser 44; c. allowing the parallel light passing through the diffuser 44 to become a diffusing light; d. allowing the diffusing light to pass through the lens 45; e. electrically connecting the pin 43 and the contacting pad 22; and f. forming an image on the image sensor 20. The detecting method imitates the light (the diffusing light) to pass through the image sensor 20 used in daily circumstances under a natural environment to increase the accuracy of detecting result. Normally, the image sensor 20 and the lens 45 are used together. Thus, the diffusing light passing through the lens 45 is similar to the result of the image sensor 20 in the daily circumstances under a natural environment. Note that the image sensor 20 may be a charge coupled device (CCD) or contact image sensors (CIS).

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A detector for detecting an image sensor, wherein the image sensor is electrically connected to a wafer and a contacting pad is disposed between the image sensor and the wafer, the detector comprising:
a parallel light source, radiating a parallel light;
a pin, electrically connected to the contacting pad; and
a diffuser, disposed between the parallel light source and the pin;
wherein the parallel light of the parallel light source passes through the diffuser, is transformed to diffusing light, and reaches the image sensor and the wafer.

2. The detector as claimed in claim 1, further comprising a holder disposed between the diffuser and the pin.

3. The detector as claimed in claim 2, further comprising a lens, the lens being held by the holder between the diffuser and the pin.

4. The detector as claimed in claim 3, wherein the holder comprises an adjusting mechanism, and the adjusting mechanism comprises an accommodating portion to contain the lens and a trimmer screw to connect to the lens, wherein the trimmer screw is rotated to move the lens.

5. The detector as claimed in claim 4, wherein the bore diameter of the accommodating portion is greater than the diameter of the lens.

6. The detector as claimed in claim 1, further comprising a printed circuit board electrically connected to the pin.

7. A detecting method for detecting an image sensor, wherein the image sensor is electrically connected to a wafer, a contacting pad is disposed between the image sensor and the wafer, and the detecting method comprises the steps of:
providing a detector having a parallel light, a pin, a diffuser and a lens;
allowing the parallel light to pass through the diffuser;
allowing the parallel light passing through the diffuser to become a diffusing light; and forming an image on the image sensor.

8. The detecting method as claimed in claim 7, further comprising allowing the diffusing light to pass through the lens.

9. The detecting method as claimed in claim 7, further comprising electrically connecting the pin and the contacting pad.
